(19) United States
(12) Patent Application Publication
(10) Pub. No.: US 2025/0245149 A1
(43) Pub. Date: Jul. 31, 2025

(54) GENERATING A LOGICAL TO PHYSICAL DATA STRUCTURE FOR A SOLID STATE DRIVE USING SECTORS OF DIFFERENT SIZES

(71) Applicant: Microchip Technology Incorporated, Chandler, AZ (US)

(72) Inventors: Nian Niles YANG, Mountain View, CA (US); Pitamber SHUKLA, San Jose, CA (US); Murthy HARI, San Jose, CA (US)

(21) Appl. No.: 18/909,937

(22) Filed: Oct. 8, 2024

Related U.S. Application Data
(60) Provisional application No. 63/625,280, filed on Jan. 25, 2024.

(51) Int. Cl. G06F 12/02

(52) U.S. Cl. CPC G06F 12/0246; G06F 2212/7201

(57) ABSTRACT

A controller may determine data type information regarding a data type to be written to a memory device. The data type information may identify a first data type associated with single-level cell data storage or a second data type associated with triple-level cell data storage or quad-level cell data storage. The controller may select, based on the data type information, a sector size for the memory device. The sector size may be a first value when the data type information identifies the first data type or may be a second value when the data type information identifies the second data type, and wherein the first value exceeds the second value. The controller may generate a logical to physical (L2P) data structure based on the sector size. The controller may store the L2P data structure in a memory of a controller of the memory device.

### RELATED APPLICATION

This application claims priority to U.S. Provisional Patent Application No. 63/625,280 entitled “GENERATING A LOGICAL TO PHYSICAL DATA STRUCTURE FOR A SOLID STATE DRIVE USING SECTORS OF DIFFERENT SIZES,” filed Jan. 25, 2024, which is incorporated herein by reference in its entirety.

### FIELD

The present disclosure generally relates to logical to physical (L2P) address mapping for non-volatile memory devices and, for example, to reducing a size of an L2P data structure of a non-volatile memory device.

### BACKGROUND

A non-volatile memory device may include a memory device that may store and retain data without external power supply. One example of a non-volatile memory device is a NAND flash memory device, without limitation. A solid-state drive (SSD) may include a plurality of non-volatile memory devices, such as NAND flash memory devices, without limitation. The non-volatile memory devices may store data that is accessible via a controller of the SSD. The controller of the SSD may maintain a table that maps logical block addresses (associated with the host computing device) to physical block addresses (of the SSD). The table may be referred to as a logical to physical (L2P) table.

### SUMMARY

In some implementations, a method comprising: determining data type information regarding a data type to be written to a memory device, wherein the data type information identifies a first data type associated with single-level cell data storage or a second data type associated with triple-level cell data storage or quad-level cell data storage; selecting, based on the data type information, a sector size for the memory device, wherein the sector size is a first value when the data type information identifies the first data type, wherein the sector size is a second value when the data type information identifies the second data type, and wherein the first value exceeds the second value; generating a logical to physical (L2P) data structure based on the sector size; and storing the L2P data structure in a memory of a controller of the memory device.

n some implementations, a memory device comprising: a controller to: receive, from an operating system, a request to store first data, receive, from the operating system, first data type information regarding a first data type, wherein the first data type is associated with single-level cell data storage; select, based on the first data type information, a first sector size of a first sector of the memory device; generate first logical block addresses, of a logical to physical (L2P) data structure, based on the first sector size; store the first data based on the first logical block addresses; receive, from the operating system, a request to store second data; receive, from the operating system, second data type information regarding a second data type, wherein the second data type is associated with triple-level cell data storage or quad-level cell data storage; select, based on the second data type information, a second sector size of a second sector of the memory device, wherein the first sector size exceeds the second sector size; generate second logical block addresses, of the L2P data structure, based on the second sector size; and store the second data based on the second logical block addresses.

In some implementations, a computer program product comprising: one or more computer readable storage media, and program instructions collectively stored on the one or more computer readable storage media, the program instructions comprising: program instructions to receive, from an operating system of a host computing device, a request to store data; program instructions to determine whether the data is associated with single-level cell data storage; program instructions to select a sector size of a sector of a memory device based on determining whether the data is associated with single-level cell data storage, wherein the sector size is a first value when the data is associated with single-level cell data storage, and wherein the sector size is a second value when the data is not associated with single-level cell data storage; program instructions to generate logical block addresses, of a logical to physical (L2P) data structure, based on the sector size; and program instructions to store the data based on the logical block addresses.

### BRIEF DESCRIPTION OF THE DRAWINGS

FIG. 1 is a diagram of an example of a device generating a logical to physical (L2P) data structure using sectors of different sizes described herein.

FIGS. 2A and 2B are flow charts of examples of generating a logical to physical (L2P) data structure using sectors of different sizes described herein.

FIGS. 3-5 are flow charts of examples of generating a logical to physical (L2P) data structure using sectors of different sizes described herein.

### DETAILED DESCRIPTION OF PREFERRED EMBODIMENTS

The following detailed description of example implementations refers to the accompanying drawings. The same reference numbers in different drawings may identify the same or similar elements.

A controller of an SSD may use a logical to physical (L2P) data structure to perform a mapping between logical block addresses (or logical addresses identified by a host device) and physical block addresses (or physical addresses of non-volatile memory devices). The L2P data structure may be stored on a memory of the controller (e.g., stored on a random-access memory (RAM)). The controller may include one or more of an application specific integrated circuit (ASIC) or firmware.

In the prior art, logical addresses of 4 bytes (B) are used to access different 4 kilobytes (KB) of data of the non-volatile memory devices. In other words, if the non-volatile memory devices are partitioned into sectors of 4 kilobytes, then the 4 bytes of LBAs may be used for addresses of up to 16 terabytes (TB) of data. While the 4 bytes of LBAs may be used for addresses of up to 16 terabytes (TB) of data, a capacity of the SSD may be increasing beyond 16 TB (e.g., increasing to at least 128 TB).

A solution to address the increased capacity of the SSD is to increase the size of logical addresses from 4 bytes to 5 bytes (to cover additional 4 KB sectors present on the SSD with 128 TB). However, this solution may create multiple technical problems. For example, this solution may increase the utilization of the storage resources of the RAM. Additionally, this solution may increase the level of complexity of an addressing design for addressing data stored on the SSD. Moreover, this solution may increase the latency associated with locating, in the L2P data structure, a physical address corresponding to a logical address.

Implementations described herein provide a technical solution to the technical problems discussed above. For example, implementations described herein are directed to using different sizes of sectors for non-volatile memory devices of an SSD based on a data type of data to be stored on non-volatile memory devices of the SSD. For example, data of a first data type may include data that is to be accessed rapidly (fast access), frequently, and in a reliable manner. Data of a second data type may include data that is to be accessed not rapidly (slow access) and infrequently. In other words, the data of the first data type may include fast access and low capacity data while the data of the second data type may include not fast access and high capacity data.

Implementations described herein may store data of the first data type in first non-volatile memory devices that are single-level cell (SLC) data storage and may store data of the second data type in second non-volatile memory devices that are triple-level cell (TLC) or quad-level cell QLC data storage. The SLC data storage may refer to non-volatile memory devices that include SLC cells and that store data in the SLC cells. The TLC or QLC data storage may refer to non-volatile memory devices that include TLC cells or QLC cells and that store data in the TLC cells or the QLC cells.

Because the data of the first data type may include fast access and low capacity data that is stored on the SLC data storage, the controller may utilize sizes of sectors (of non-memory devices) that exceed 4 KB, such as 8 KB or 16 KB, without limitation. In other words, the controller may use an address that is 4 B to allocate a portion of the SLC data storage to store 8 KB of data or to store 16 KB of data. In this regard, the controller may generate an entry (for an L2P table) that maps a 4 B logical address to a 4 B physical address, with the 4 B physical address being used to access 8 KB of data or to access 16 KB of data.

By using addresses of 4 B to access 8 K of data or 16 KB of data, implementations described herein may access twice the amount of data or four times the amount of data that would have been accessed for non-volatile memory devices with 4 KB sectors. In other words, implementations may utilize half an address space (or half a range of addresses) to access data of non-volatile memory devices. Accordingly, implementations described herein may preserve a storage capacity of a memory of the controller that stores the L2P table.

Because the data of the second data type may include data that is to be accessed not rapidly (slow access) and infrequently that is stored on the TLC or QLC data storage, the controller may utilize sizes of sectors (of non-memory devices) that are 4 KB, or, in some instances, 512 B. In other words, the controller may use an address that is 4 B to allocate a portion of the TLC data storage or QLC data storage to store 4 KB of data or to store 512 B of data. In this regard, the controller may generate an entry (for an L2P table) that maps a 4 B logical address to a 4 B physical address, with the 4 B physical address being used to access 4 KB of data or to access 512 B of data.

In some implementations, the controller may encode data, using an error correction code (ECC) component, to obtain encoded data. In some examples, the ECC component may encode 8 KB of data or 16 KB of data when the controller accesses the first non-volatile memory devices that utilize sizes of sectors (of non-memory devices) that exceed 4 KB, such as 8 KB or 16 KB, without limitation. A size of the data may be based on the size of the sector (also referred to as “sector size”) selected by the controller. In other words, the controller may encode data of different sizes that are based on the size of the sector.

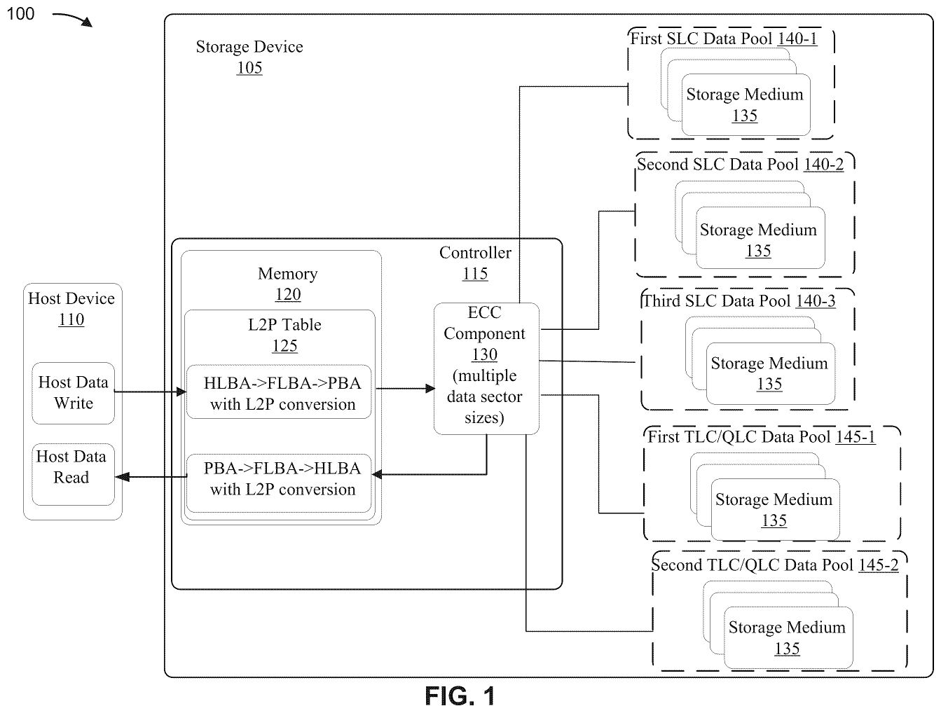

FIG. 1 is a diagram of an example 100 of a device generating a logical to physical (L2P) data structure using sectors of different sizes described herein. Example 100 describes components and operations associated with a storage device 105. In some implementations, storage device 105 may include a solid state drive (SSD). As shown in FIG. 1, storage device 105 may be associated with a host device 110. Host device 110 may access data (also referred to as “host data”) stored by storage device 105. For example, as shown in FIG. 1, host device 110 may initiate a host data write operation (e.g., a write operation) to write the host data to storage device 105 (e.g., to store the data on storage device 105) and may initiate a host read operation (e.g., a read operation) to read the host data from storage device 105.

Host device 110 may include one or more devices capable of receiving, generating, storing, processing, and/or providing information associated with generating an L2P data structure (or L2P table), as described elsewhere herein. The host device 110 may include a communication device and a computing device. For example, the host device 110 may include a wireless communication device, a mobile phone, a user equipment, a laptop computer, a tablet computer, a desktop computer, a wearable communication device (e.g., a smart wristwatch, a pair of smart eyeglasses, a head mounted display, or a virtual reality headset), or a similar type of device.

As shown in FIG. 1, storage device 105 may include a controller 115. Controller 115 may include one or more of an application specific integrated circuit (ASIC) or firmware. Controller 115 may cause functions to be performed on storage device 105, such as read operations, write operations, erase operations, garbage collection operations, among other examples. Controller 115 may include a memory 120 and an error correction code (ECC) component 130. Memory 120 may include a RAM (e.g., dynamic random access memory (DRAM), a synchronous DRAM (SDRAM), among other examples).

As shown in FIG. 1, memory 120 may include an L2P table 125 (or an L2P data structure). L2P table 125 may store a mapping between host logical block addresses (or logical addresses identified by host device 110) and physical block addresses (or physical addresses of non-volatile memory devices of storage device 105). In some implementations, L2P table 125 may be generated by controller 115.

In some implementations, controller 115 may identify a host logical block address (HLBA) associated with the host data by which host device 110 may reference the host data in a future read operation. As shown in FIG. 1, controller 115 may convert the HLBA to a flash logical block address (FLBA) or other local logical block address, and then may link the FLBA to a physical block address (PBA) using an L2P conversion. The HLBA may include a logical address, of the host data, determined by host device 110. The PBA may include a physical address, of the host data, determined based on the L2P conversion. The HLBA may be converted to an FLBA which may cover more than one HLBA. For example, an HLBA may cover 512 B of data while an FLBA may cover 8 KB data, which may include 16 of 512 B data. The FLBA may be mapped to the PBA, which is a physical location on storage device 105. In some situations, the HLBA may have different PBAs at different times. Conversely, controller 115 may convert a PBA to an FLBA or other local logical block address, and then may link the FLBA to a physical block address (PBA) using an L2P conversion. In this way, the host device may send a static address associated with the host data, controller 115 may link the address known to host device 110 to an address known to storage device 105 (the FLBA), and controller 115 may link the address known to storage device 105 to a physical address of the host data within a storage medium of storage device 105.

Controller 115 may store the links between the HLBA, the FLBA, and the PBA in L2P table 125. In some aspects, the host data may be moved within the storage medium or between storage mediums of storage device 105, which controller 115 may note in the link between the FLBA and the physical location. In this way, the HLBA may bypass being updated when the host data is moved to a new PBA.

Implementations described herein are directed to using different sizes of sectors for storage mediums (e.g., non-volatile memory devices) of storage device 105 based on a data type of data to be stored on non-volatile memory devices of the SSD. Data of the first data type may include fast access and low capacity data that is stored on the SLC data storage. Accordingly, controller 115 may utilize sizes of sectors (of non-memory devices) that exceed 4 KB, such as 8 KB or 16 KB, without limitation.

In other words, controller 115 may use an address that is 4 B to allocate a portion of the SLC data storage to store 8 KB of data or to store 16 KB of data. In this regard, controller 115 may generate an entry (for an L2P table) that maps a 4 B logical address to a 4 B physical address, with the 4 B physical address being used to access 8 KB of data or to access 16 KB of data.

If the data is not associated with SLC data storage (e.g., associated with triple-level cell (TLC) data storage or quad-level cell (QLC) data storage), controller 115 may maintain the size of the sector at 4 KB. In this regard, controller 115 may generate an entry (for an L2P table) that maps a 4 B logical address to a 4 B physical address, with the 4 B physical address being used to access 4 KB of data. In some situations, if the data is not associated with SLC data storage and the data is to be stored using sequential write operations, the controller may increase the size of the sector to 8 KB or 16 KB. In this regard, controller 115 may generate an entry (for an L2P table) that maps a 4 B logical address to a 4 B physical address, with the 4 B physical address being used to access 8 KB of data or to access 16 KB of data. Alternatively, if the data is not associated with SLC data storage and the data is to be stored using random write operations, controller 115 may maintain the size of the sector at 4 KB. In this regard, controller 115 may generate an entry (for an L2P table) that maps a 4 B logical address to a 4 B physical address, with the 4 B physical address being used to access 4 KB of data.

ECC component 130 may include an ECC engine. ECC component 130 may perform error correction code encoding on the host data. In some implementations, the error correction code encoding may include adding redundancy, parity bits, or other information that can later be used to identify errors in the host data when read from the storage medium. Controller 115 may provide the host data, after encoding, via flash control channels (not shown) to write on storage mediums of storage device 105.

In some implementations, ECC component 130 may perform error correction code encoding on data of different sizes. A size of the data may be based on the sizes of the sectors. In this regard, ECC component 130 may perform error correction code encoding on 4 KB of data, 8 KB of data, or 16 KB of data, without limitation.

As shown in FIG. 1, storage device 105 may include storage mediums 135 (individually “storage medium 135” and collectively “storage mediums 135”). A storage medium 135 may include anon-volatile memory device. For example, the storage medium 135 may include a NAND memory device. As shown in FIG. 1, storage mediums 135 may be organized by data pools. A “data pool” may be used to refer to part of the SSD storage media that stores a given type of data. For example, an SLC data pool may refer to a collection of blocks dedicated for storing SLC data type (e.g., data type of data stored in SLC cells). For instance, the collection of blocks of the SLC data pool may include SLC cells and may store data in the SLC cells. Similarly, a TLC data pool may refer to a collection of blocks dedicated for storing TLC data type (e.g., data type of data stored in TLC cells). For instance, the collection of blocks of the TLC data pool may include TLC cells and may store data in the TLC cells. A QLC data pool may include QLC cells and may store data in the QLC cells.

As shown in FIG. 1, storage device 105 may include a first SLC data pool 140-1, a second SLC data pool 140-2, and a third SLC data pool 140-3 (collectively “SLC data pools 140”). An SLC data pool 140 may identify different uses for blocks of storage mediums 135. For example, an SLC data pool 140 may be used for storing data structures used by controller 115 (e.g., firmware management tables). Alternatively, an SLC data pool 140 may be used for storing host data associated with fast access. Alternatively, an SLC data pool 140 may be used for infrastructure data of storage device 105, such as for booting of an operating system, for logging into the operating system, or for metadata storage. SLC data pools 140 may be considered SLC storage. As explained herein, controller 115 may use a sector size that exceeds 4 KB (e.g., 8 K or 16 KB) when mapping HLBAs to PBAs of an SLC data pool 140. For example, controller 115 may map 4 B logical address to a 4 B physical address of an SLC data pool 140, with the 4 B physical address being used to access 8 KB of data or to access 16 KB of data stored in the SLC data pool 140.

SLC data pools 140 may include subpools for high speed data write. As an example, first SLC data pool 140-1 may be a data pool for specific high speed data write and buffering, such as an operating system. As an example, second SLC data pool 140-2 may be a data pool for specific high speed data write and buffering, such as TLC buffering. In some implementations, TLC buffering may refer to writing the host data to an SLC storage at a higher speed, then transferring the host data from the SLC storage to a TLC storage when there is no host access activity. In other words, the host data is not written to the TLC storage directly from host device 110. As an example, third SLC data pool 140-3 may be a data pool for specific high speed data write and buffering, such as firmware metadata (e.g., metadata associated with controller 115).

As shown in FIG. 1, storage device 105 may include a first TLC/QLC data pool 145-1 and a second TLC/QLC data pool 145-2 (collectively “TLC/QLC data pools 145”). TLC/QLC data pools 145 may be considered TLC/QLC storage. As an example, first TLC/QLC data pool 145-1 may be a data pool for sequential user data. As an example, second TLC/QLC data pool 145-2 may be a data pool for random user data.

As explained herein, controller 115 may use a sector size of 4 KB when mapping HLBAs to PBAs of a TLC/QLC data pool 145. For example, controller 115 may map 4 B logical address to a 4 B physical address of the TLC/QLC data pool 145, with the 4 B physical address being used to access 4 KB of data stored in the TLC/QLC data pool 145. In some situations, controller 115 may use a sector size that exceeds 4 KB when mapping HLBAs to PBAs of a TLC/QLC data pool 145. TLC/QLC data pools 145 may include subpools for data that is to be written sequentially or is to be written randomly. In some examples, sequentially written data may be written at a speed that exceeds a speed at which randomly written data may be written.

In some implementations, host device 110 may cause storage mediums 135 to be organized into different data pools, such as the SLC data pools 140 and the TLC/QLC data pools 145. For example, host device 110 may provide information to cause storage mediums 135 to be organized into different pools of static SLC, TLC/QLC, or hybrid SLC areas for different purposes. For instance, host device 110 may indicate that a first portion of storage mediums 135 is to be used as SLC data storage and that a second portion of storage mediums 135 is to be used as TLC data storage. In some examples, an SLC to TLC folding may occur between an SLC data pool 140 and a TLC/QLC data pool 145 (e.g., multiple blocks of SLC cells may be combined into a single TLC block). In some examples, a TLC to SLC data backing may occur between an SLC data pool 140 and a TLC/QLC data pool 145. For example, an SLC data pool 140 may provide data backup for data stored by a TLC/QLC data pool 145. Alternatively, a TLC/QLC data pool 145 may provide data backup for data stored by a SLC data pool 140.

By using addresses of 4 B to access 8 K of data or 16 KB of data, implementations described herein may access twice the amount of data or four times the amount of data that would have been accessed for non-volatile memory devices with 4 KB sectors. In other words, implementations may utilize half an address space (or half a range of addresses) to access data of non-volatile memory devices. Accordingly, implementations described herein may preserve a storage capacity of a memory of the controller that stores an L2P table.

As indicated above, FIG. 1 is provided as an example. Other examples may differ from what is described with regard to FIG. 1. The number and arrangement of devices shown in FIG. 1 is provided as an example. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) shown in FIG. 1 may perform one or more functions described as being performed by another set of devices shown in FIG. 1.

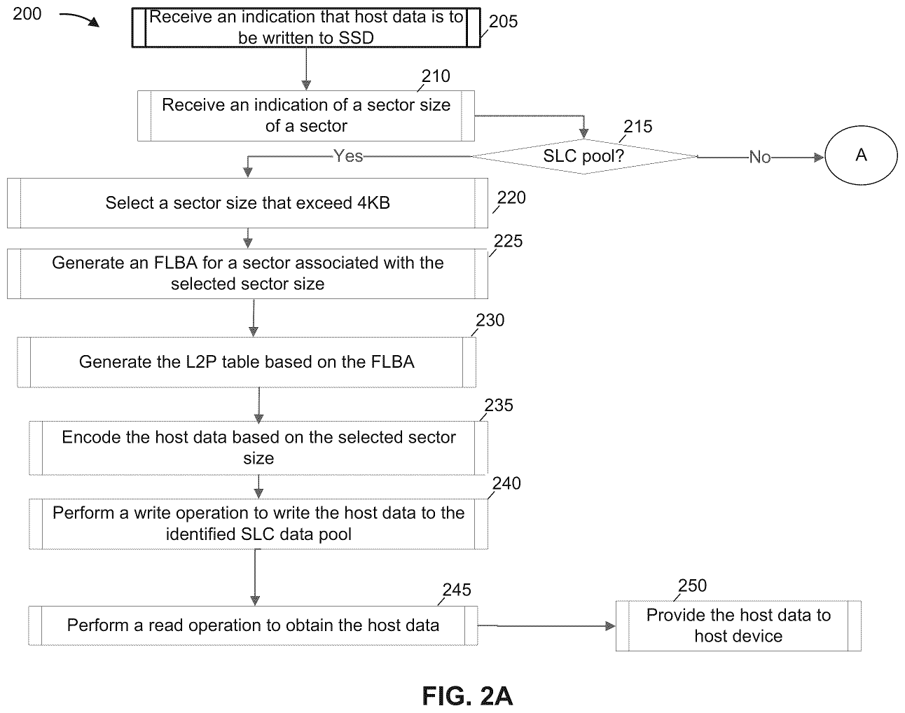

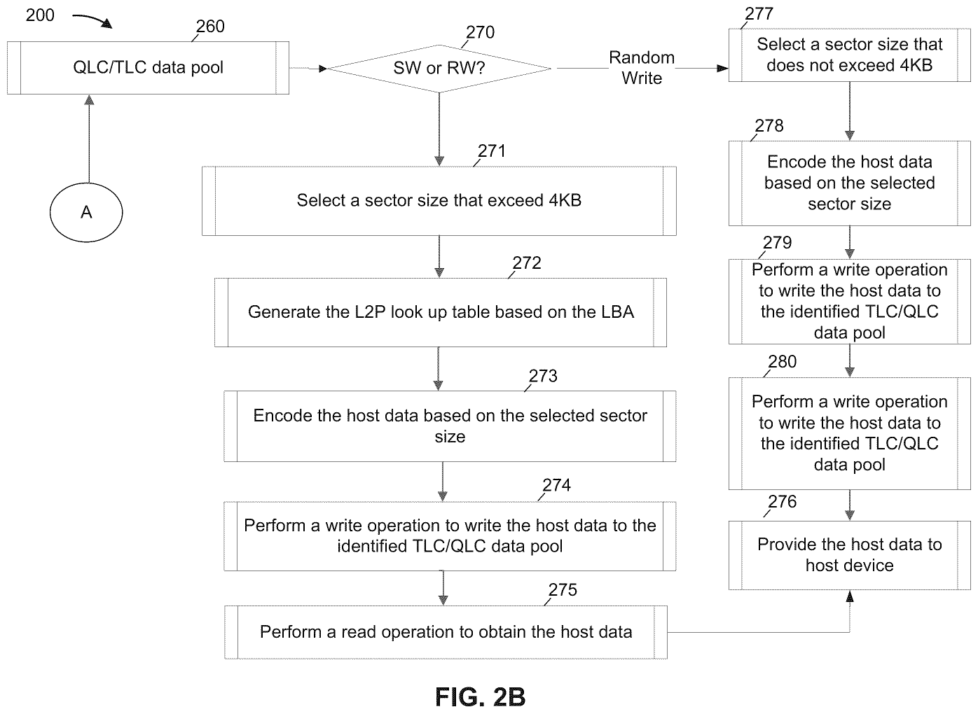

FIGS. 2A and 2B are flowcharts of an example process 200 associated with generating a logical to physical data structure for a solid state drive using sectors of different sizes. In some implementations, one or more process blocks of FIGS. 2A and 2B may be performed by a controller (e.g., controller 115). In some implementations, one or more process blocks of FIGS. 2A and 2B may be performed by another device or a group of devices separate from or including the controller, such as an ECC component (e.g., ECC component 130).

As shown in FIG. 2A, process 200 may include receiving an indication (from host device 110) that host data is to be written to storage device 105 (block 205). For example, controller 115 may receive an indication (from host device 110) that data is to be written to a data pool of storage device 105. In some implementations, controller 115 may receive the indication based on host device 110 providing a request to initiate a write operation to write the host data on storage device 105. In other words, controller 115 may receive the indication based on host device 110 providing a write command to store the host data on storage device 105.

In some examples, the request (e.g., the write command) may include information regarding the host data (e.g., metadata regarding the host data). For example, the metadata may include data type information regarding a data type of the host data. The data type information may identify a first data type associated with SLC data storage or a second data type associated with TLC data storage or QLC data storage. For example, the data type information may identify the first data type by indicating that the host data is data of an operating system, firmware metadata, or data for TLC buffering. In some examples, the request (e.g., the write command) may identify an HLBA for the host data.

As shown in FIG. 2A, process 200 may include receiving an indication of a sector size of a sector (block 210). For example, controller 115 may receive an indication (from host device 110) of a sector size of a sector of storage device 105. In some implementations, controller 115 may receive the indication in conjunction with the request to initiate the write operation. As an example, host device 110 may request a 4 KB sector size or a 512 B sector size, among other examples. In this regard, in some situations, controller 115 may cause data to be written to the sector of storage device 105 with the sector size identified by host device 110.

As shown in FIG. 2A, process 200 may include determining whether the host data is to be written to an SLC data pool (block 215). For example, controller 115 may determine whether the host data is to be written to an SLC data pool 140. In some implementations, controller 115 may determine whether the host data is to be written to an SLC data pool 140 based on the data type information regarding a data type of the host data. The data type information may identify a first data type associated with SLC data storage or a second data type associated with TLC data storage or QLC data storage. For example, the data type information may identify the first data type by indicating that the host data is data of an operating system, firmware metadata, or data for TLC buffering.

As shown in FIG. 2A, process 200 may include selecting a sector size that exceeds 4 KB (block 220). For example, based on determining that the host data is to be written to an SLC data pool 140, controller 115 may determine that a sector size that exceeds 4 KB is to be used to store the host data. In some implementations, based on the data type information identifying the first data type, controller 115 may determine that the host data is to be written to an SLC data pool 140. Accordingly, controller 115 may determine that a sector size of 8 K or 16 KB is to be used to store the host data. Controller 115 may identify a SLC data pool 140.

As shown in FIG. 2A, process 200 may include generating an FLBA for a sector associated with the selected sector size (block 225). For example, after selecting the selected sector size, controller 115 may generate an FLBA for a sector of storage device 105 with the selected sector size. In some situations, the FLBA may be generated based on the HBLA identified in the request (e.g., the write command). For example, controller 115 may convert the

HBLA to the FBLA. In some situations, generating the FLBA may involve some aggregation operation of the host data to be assembled for a larger sector (e.g., for a sector with the selected sector size). For example, the aggregation operation may involve aggregating the host data in light of the larger sector. In some implementations, during the aggregation operation, the host data may be buffered in a memory associated with controller 115 (e.g., a double data rate (DDR) memory or a random access memory (RAM). Also, once started for programming into an SLC data pool 140, the host data will not be subjected to data loss caused by events such as power loss.

As shown in FIG. 2A, process 200 may include generating an L2P table based on the FLBA (block 230). For example, controller 115 may generate an L2P table to store a mapping for the FLBA and a PBA corresponding to the sector. In some implementations, controller 115 generate an entry, for the L2P table, that maps the FLBA to the PBA. In some implementations, the L2P table includes an existing entry that identifies the PBA mapped to an existing FLBA. In some such implementations, controller 115 may update the existing entry to map the PBA to the LBA generated by controller 115.

In some examples, the FLBA may be added to metadata header information. The metadata may include bits indicating that the sector encompasses an appropriate number of bits. The metadata may be provided with user data associated with the FLBA. In some examples, the metadata may include 32 B (or 256 bits).

As shown in FIG. 2A, process 200 may include encoding the host data based on the selected sector size (block 235). For example, controller 115 may use ECC component 130 to perform error correction code encoding on the host data to obtain encoded host data. In some implementations, the error correction code encoding may include adding redundancy, parity bits, or other information that can later be used to identify errors in the host data when read from a storage medium 135.

As explained, ECC component 130 may encode 4 KB of data, 8 K of data, 16 KB of data, among other examples. For example, ECC component 130 may generate and add ECC information (e.g., ECC bits) to different sizes of data. The ECC information may be used to encode the data. In some implementations, content of the ECC information (e.g., actual bits) may be based on a size of data, a size of the information may be based on a size of data, or a combination of the foregoing. As an example, actual bits used to encode 4 KB of data may be different than actual bits used to encode 8 KB of data. As another example, actual bits used to encode 16 KB of data may be different than actual bits used to encode 4K of data and 8 K of data. With respect to encoding 8 K of data or 16 KB of data, in some situations the sector may include more than one ECC data chunk. Ideally, the ECC data chunk may be adjusted as well, but if not, the sector may have the ECC data chunks ordered sequentially, or have an indictor in the very first data chunk to indicate how the ECC data chunks are aligned with the sector (e.g., to indicate how the ECC data chunks are stored in the sector). As used herein, an ECC data chunk may include data that may be used by an ECC engine (e.g., of ECC component 130) for error correction and detection. As an example, an ECC data chunk may refer to an ECC codeword. In some implementations, the ECC data chunk may be adjusted as a size of the data to be encoded varies. For example, bits of the ECC data chunk may be changed as the data to be encoded varies between 4 KB, 8 K, and 16 KB. Similarly, a size of the ECC data chunk may be changed as the data to be encoded varies between 4 KB, 8 K, and 16 KB.

As shown in FIG. 2A, process 200 may include performing a write operation to write the host data to the identified SLC data pool (block 240). For example, controller 115 may perform a write operation (e.g., data programming operation) to write the encoded host data to the identified SLC data pool 140 after performing the error correction code encoding on the host data.

As shown in FIG. 2A, process 200 may include performing a read operation (block 245). For example, after the host data has been stored on the identified SLC data pool 140, host device 110 may initiate a read command and controller 115 may perform a read operation based on the read command. The read command may identify the LBA. In this regard, based on the LBA identified by the read command, controller 115 may perform a lookup of the L2P table, using the LBA, to identify the PBA corresponding to the LBA.

In some implementations, as part of the read operation, an entirety of the selected sector may be sensed to obtain the encoded host data. The encoded host data may be decoded by ECC component 130 to obtain decoded host data.

As shown in FIG. 2A, process 200 may include providing the host data to host device (block 250). For example, after the host data has been decoded, controller 115 may be provided the decoded host data to host device 110, based on the read command.

As shown in FIG. 2B, process 200 may include determining that the host data is to be written to a QLC/TLC data pool (block 260). For example, based on determining that the host data is not to be written to an SLC data pool 140, controller 115 may determine that the host data is to be written to a TLC/QLC data pool 145. In some implementations, controller 115 may determine that the host data is to be written to a TLC/QLC data pool 145 based on the data type information regarding the data type of the host data. The data type information may identify the second data type associated with TLC data storage or QLC data storage. For example, the data type information may identify the second data type by indicating that the host data is user data.

As shown in FIG. 2B, process 200 may include determining whether the host data is to be written using a sequential write operation or using a random write operation (block 270). In some implementations, the write command (from host device 110) may include information indicating whether the host data is to be written using a sequential write operation or using a random write operation. For example, the information may identify a size of the host data. In this regard, if the size of the host data satisfies a size threshold, controller 115 may determine that a sequential write operation is to be performed to write the host data to storage device 105. As an example, the host data may be data of a gaming application and the host data may exceed 100 MB. In this regard, based on the host data exceeding 100 MB, controller 115 may determine that a sequential write operation is to be performed to write the host data to storage device 105. Alternatively, if the size of the host data does not satisfy the size threshold, controller 115 may determine that a random write operation is to be performed to write the host data to storage device 105. As an example, the host data may be data of a picture (captured by host device 110) and the host data may be 5M (e.g., less than 100 MB). In this regard, based on the host data being less than 100 MB, controller 115 may determine that a random write operation is to be performed to write the host data to storage device 105.

As shown in FIG. 2B, process 200 may include selecting a sector size that exceeds 4 KB (block 271). In some implementations, controller 115 may determine that the size of the host data satisfies the size threshold. Accordingly, controller 115 may determine that a sequential write operation is to be performed to write the host data to storage device 105. Based on determining that the sequential write operation is to be performed, controller 115 may determine that a sector size that exceeds 4 KB is to be used to store the host data. In some implementations, based on the data type information identifying the second data type and based on determining that the sequential write operation is to be used to stored data, controller 115 may determine that the host data is to be written to a TLC/QLC data pool 145. Accordingly, controller 115 may determine that a sector size of 8 K or 16 KB is to be used to store the host data. Controller 115 may identify a TLC/QLC data pool 145.

Process 200 may include generating an LBA for a sector associated with the selected sector size, in a manner similar the manner described above in connection with block 225.

As shown in FIG. 2B, process 200 may include generating an L2P table based on the LBA (block 272). For example, controller 115 may generate an L2P table to store a mapping for the LBA and a PBA corresponding to the sector, in a manner similar to the manner described above in connection with block 230.

As shown in FIG. 2B, process 200 may include encoding the host data based on the selected sector size (block 273). For example, controller 115 may use ECC component 130 to perform error correction code encoding on the host data to obtain encoded host data, as described herein and in connection with block 235.

As shown in FIG. 2B, process 200 may include performing a write operation to write the host data to the identified TLC/QLC data pool (block 274). For example, controller 115 may perform a write operation (e.g., data programming operation) to write the encoded host data to the identified TLC/QLC data pool 145 after performing the error correction code encoding on the host data, as described herein and in connection with block 240.

As shown in FIG. 2B, process 200 may include performing a read operation (block 275). For example, after the host data has been stored on the identified TLC/QLC data pool 145, host device 110 may initiate a read command and controller 115 may perform a read operation based on the read command, in a manner similar to the manner described in connection with block 245.

As shown in FIG. 2B, process 200 may include providing the host data to host device (block 276). For example, controller 115 may provide the decoded host data to host device 110, in a manner similar to the manner described above in connection with block 250.

As shown in FIG. 2B, process 200 may include selecting a sector size that does not exceed 4 KB (block 277). In some implementations, controller 115 may determine that the size of the host data does not satisfy the size threshold. Accordingly, controller 115 may determine that a random write operation is to be performed to write the host data to storage device 105. Based on determining that the random write operation is to be performed, controller 115 may determine that a sector size that does not exceed 4 KB is to be used to store the host data. For example, controller 115 may determine that a sector size of 4 KB or 512 B is to be used. In some implementations, based on the data type information identifying the second data type, controller 115 may determine that the host data is to be written to a TLC/QLC data pool 145.

As shown in FIG. 2B, process 200 may include encoding the host data based on the selected sector size (block 278). For example, controller 115 may use ECC component 130 to perform error correction code encoding on the host data to obtain encoded host data, as described herein and in connection with blocks 235 and 273.

As shown in FIG. 2B, process 200 may include performing a write operation to write the host data to the identified TLC/QLC data pool (block 279). For example, controller 115 may perform a write operation (e.g., data programming operation) to write the encoded host data to the identified TLC/QLC data pool 145 after performing the error correction code encoding on the host data, as described herein and in connection with blocks 240 and 274.

Process 200 may include performing a read operation. For example, after the host data has been stored on the identified TLC/QLC data pool 145, host device 110 may initiate a read command and controller 115 may perform a read operation based on the read command, in a manner similar to the manner described in connection with blocks 245 and 275.

As shown in FIG. 2B, process 200 may include providing the host data to host device (block 280). For example, controller 115 may provide the decoded host data to host device 110, in a manner similar to the manner described above in connection with blocks 250 and 276.

Although FIGS. 2A and 2B show example blocks of process 300, in some implementations, process 200 may include additional blocks, fewer blocks, different blocks, or differently arranged blocks than those depicted in FIGS. 2A and 2B. Additionally, or alternatively, two or more of the blocks of process 200 may be performed in parallel.

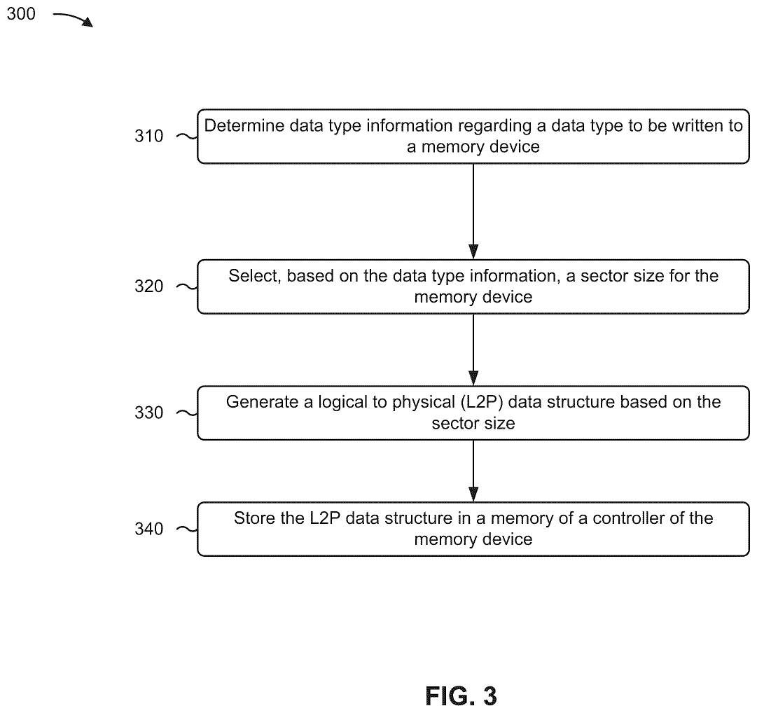

FIG. 3 is a flowchart of an example process 300 associated with generating a logical to physical data structure for a solid state drive using sectors of different sizes. In some implementations, one or more process blocks of FIG. 3 may be performed by a controller (e.g., controller 115). In some implementations, one or more process blocks of FIG. 3 may be performed by another device or a group of devices separate from or including the controller, such as an ECC component (e.g., ECC component 130).

As shown in FIG. 3, process 300 may include determining data type information regarding a data type to be written to a memory device (block 310). For example, the controller may determine data type information regarding a data type to be written to a memory device, as described above in connection with block 205. In some implementations, the data type information identifies a first data type associated with single-level cell data storage or a second data type associated with triple-level cell data storage or quad-level cell data storage.

As further shown in FIG. 3, process 300 may include selecting, based on the data type information, a sector size for the memory device (block 320). For example, the controller may select, based on the data type information, a sector size for the memory device, as described above in connection with block 220, block 271, or block 277. In some implementations, the sector size may be a first value when the data type information identifies the first data type. The sector size may be a second value when the data type information identifies the second data type. The first value may exceed the second value.

As further shown in FIG. 3, process 300 may include generating a logical to physical (L2P) data structure based on the sector size (block 330). For example, the controller may generate a logical to physical (L2P) data structure based on the sector size, as described above in connection with block 230 or block 272.

As further shown in FIG. 3, process 300 may include storing the L2P data structure in a memory of a controller of the memory device (block 340). For example, the controller may store the L2P data structure in a memory of a controller of the memory device, as described above in connection with FIG. 1.

In some implementations, the sector size is the first value when the data type information identifies the second data type and when data is to be written to the memory device using a sequential write operation.

In some implementations, the sector size is the second value when the data type information identifies the second data type and when data is to be written to the memory device using a random write operation.

In some implementations, process 300 includes encoding data, using an error correction code (ECC) component, to obtain encoded data, wherein a size of the data is based on the sector size, and wherein the data is received from a host computing device, and storing, based on the L2P data structure, the encoded data in a location of the memory device.

In some implementations, the size of the data is the first value when the sector size is the first value, and wherein the size of the data is the second value when the sector size is the second value.

In some implementations, process 300 includes receiving information regarding the first data type associated with single-level cell data storage, and receiving a request to store data of the operating system.

In some implementations, process 300 includes receiving information regarding the first data type associated with single-level cell data storage, and receiving a request to store firmware metadata.

Although FIG. 3 shows example blocks of process 300, in some implementations, process 300 may include additional blocks, fewer blocks, different blocks, or differently arranged blocks than those depicted in FIG. 3. Additionally, or alternatively, two or more of the blocks of process 300 may be performed in parallel.

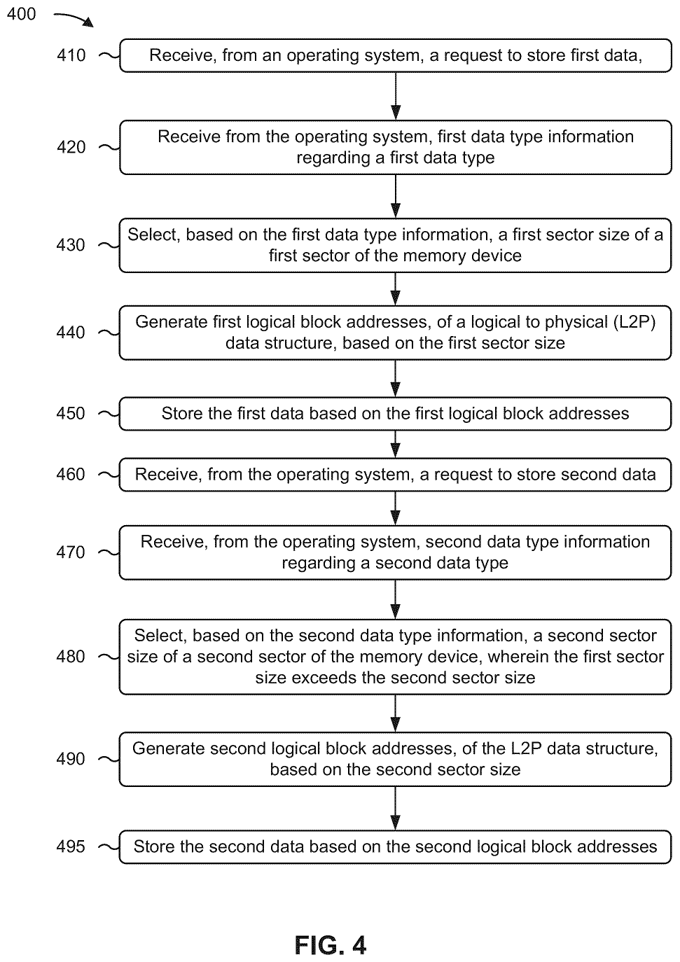

FIG. 4 is a flowchart of an example process 400 associated with generating a logical to physical data structure for a solid state drive using sectors of different sizes. In some implementations, one or more process blocks of FIG. 4 may be performed by a controller (e.g., controller 115). In some implementations, one or more process blocks of FIG. 4 may be performed by another device or a group of devices separate from or including the controller, such as an ECC component (e.g., ECC component 130).

As shown in FIG. 4, process 400 may include receiving, from an operating system, a request to store first data (block 410). For example, the controller may receive, from an operating system, a request to store first data, as described above in connection with block 205.

As further shown in FIG. 4, process 400 may include receiving, from the operating system, first data type information regarding a first data type (block 420). For example, the controller may receive, from the operating system, first data type information regarding a first data type, as described above in connection with block 210. In some implementations, the first data type is associated with single-level cell data storage.

As further shown in FIG. 4, process 400 may include selecting, based on the first data type information, a first sector size of a first sector of the memory device (block 430). For example, the controller may select, based on the first data type information, a first sector size of a first sector of the memory device, as described above in connection with block 220.

As further shown in FIG. 4, process 400 may include generating first logical block addresses, of a logical to physical (L2P) data structure, based on the first sector size (block 440). For example, the controller may generate first logical block addresses, of a logical to physical (L2P) data structure, based on the first sector size, as described above in connection with block 225.

As further shown in FIG. 4, process 400 may include storing the first data based on the first logical block addresses (block 450). For example, the controller may store the first data based on the first logical block addresses, as described above in connection with FIG. 1.

As further shown in FIG. 4, process 400 may include receiving, from the operating system, a request to store second data (block 460). For example, the controller may receive, from the operating system, a request to store second data, as described above in connection with block 205.

As further shown in FIG. 4, process 400 may include receiving, from the operating system, second data type information regarding a second data type (block 470). For example, the controller may receive, from the operating system, second data type information regarding a second data type, as described above in connection with block 260. In some implementations, the second data type is associated with triple-level cell data storage or quad-level cell data storage.

As further shown in FIG. 4, process 400 may include selecting, based on the second data type information, a second sector size of a second sector of the memory device (block 480). For example, the controller may select, based on the second data type information, a second sector size of a second sector of the memory device, as described above in connection with block 271 or block 277. In some implementations, the first sector size exceeds the second sector size.

As further shown in FIG. 4, process 400 may include generating second logical block addresses, of the L2P data structure, based on the second sector size (block 490). For example, the controller may generate second logical block addresses, of the L2P data structure, based on the second sector size, as described above in connection with block 272.

As further shown in FIG. 4, process 400 may include storing the second data based on the second logical block addresses (block 495). For example, the controller may store the second data based on the second logical block addresses, as described above in connection with block 274 or block 279.

In some implementations, the controller may store the first data in a first portion, of the memory device, dedicated to data of the first data type based on the first logical block addresses.

In some implementations, the controller may store the second data in a second portion, of the memory device, dedicated to data of the second data type based on the second logical block addresses.

In some implementations, the controller may encode a portion of the first data, using an error correction code (ECC) component, to obtain encoded first data, wherein a size of the portion of the first data is based on the first sector size, and storing the encoded first data in a first location of the memory device.

In some implementations, the controller is to encode a portion of the second data, using the ECC component, to obtain encoded second data, wherein a size of the portion of the second data is based on the second sector size, and storing the encoded second data in a second location of the memory device.

In some implementations, the first data includes firmware metadata or data of the operating system.

Although FIG. 4 shows example blocks of process 400, in some implementations, process 400 may include additional blocks, fewer blocks, different blocks, or differently arranged blocks than those depicted in FIG. 4. Additionally, or alternatively, two or more of the blocks of process 400 may be performed in parallel.

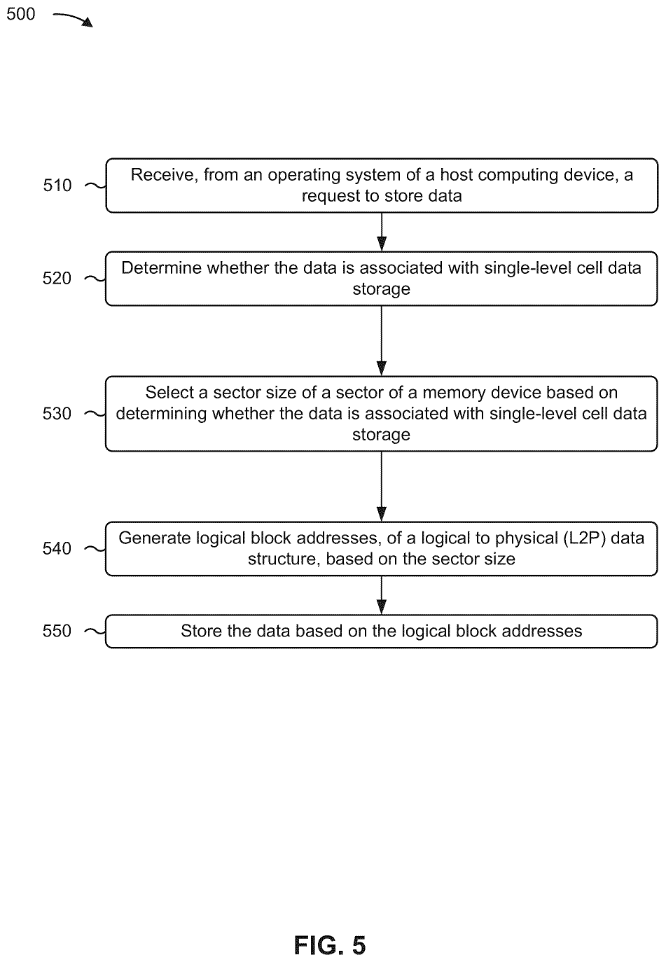

FIG. 5 is a flowchart of an example process 500 associated with generating a logical to physical data structure for a solid state drive using sectors of different sizes. In some implementations, one or more process blocks of FIG. 5 may be performed by a controller (e.g., controller 115). In some implementations, one or more process blocks of FIG. 5 may be performed by another device or a group of devices separate from or including the controller, such as an ECC component (e.g., ECC component 130).

As shown in FIG. 5, process 500 may include receiving, from an operating system of a host computing device, a request to store data (block 510). For example, the controller may receive, from an operating system of a host computing device, a request to store data, as described above in connection with block 205.

As further shown in FIG. 5, process 500 may include determining whether the data is associated with single-level cell data storage (block 520). For example, the controller may determine whether the data is associated with single-level cell data storage, as described above in connection with block 215.

As further shown in FIG. 5, process 500 may include selecting a sector size of a sector of a memory device based on determining whether the data is associated with single-level cell data storage, wherein the sector size is a first value when the data is associated with single-level cell data storage, and wherein the sector size is a second value when the data is not associated with single-level cell data storage (block 530). For example, the controller may select a sector size of a sector of a memory device based on determining whether the data is associated with single-level cell data storage, wherein the sector size is a first value when the data is associated with single-level cell data storage, and wherein the sector size is a second value when the data is not associated with single-level cell data storage, as described above. In some implementations, the sector size is a first value when the data is associated with single-level cell data storage. In some implementations, the sector size is a second value when the data is not associated with single-level cell data storage.

As further shown in FIG. 5, process 500 may include generating logical block addresses, of a logical to physical (L2P) data structure, based on the sector size (block 540). For example, the controller may generate logical block addresses, of a logical to physical (L2P) data structure, based on the sector size, as described above in connection with block 230 or block 272.

As further shown in FIG. 5, process 500 may include storing the data based on the logical block addresses (block 550). For example, the controller may store the data based on the logical block addresses, as described above in connection with block 240, block 274, or block 280.

In some implementations, the program instructions comprise program instructions to determine that the data is associated with single-level cell data storage, and program instructions to select the first value as the sector size based on determining that the data is associated with single-level cell data storage.

In some implementations, the program instructions comprise programming instructions to encode a portion of the data, using an error correction code (ECC) component, to obtain encoded data, wherein a size of the portion of the data is based on the first value, and storing the encoded data in a location of the memory device based on the L2P data structure.

In some implementations, the data includes firmware metadata or data of the operating system.

In some implementations, the program instructions comprise program instructions to determine that the data is not associated with single-level cell data storage, and program instructions to select the second value as the sector size based on determining that the data is not associated with single-level cell data storage.

In some implementations, the sector size is a second value when the data is associated with triple-level cell data storage or quad-level cell data storage.

Although FIG. 5 shows example blocks of process 500, in some implementations, process 500 may include additional blocks, fewer blocks, different blocks, or differently arranged blocks than those depicted in FIG. 5. Additionally, or alternatively, two or more of the blocks of process 500 may be performed in parallel.

As used herein, the term “component” is intended to be broadly construed as hardware, firmware, or a combination of hardware and software. It will be apparent that systems and/or methods described herein may be implemented in different forms of hardware, firmware, and/or a combination of hardware and software. The actual specialized control hardware or software code used to implement these systems and/or methods is not limiting of the implementations. Thus, the operation and behavior of the systems and/or methods are described herein without reference to specific software code-it being understood that software and hardware can be used to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

To the extent the aforementioned implementations collect, store, or employ personal information of individuals, it should be understood that such information shall be used in accordance with all applicable laws concerning protection of personal information. Additionally, the collection, storage, and use of such information can be subject to consent of the individual to such activity, for example, through well known “opt-in” or “opt-out” processes as can be appropriate for the situation and type of information. Storage and use of personal information can be in an appropriately secure manner reflective of the type of information, for example, through various encryption and anonymization techniques for particularly sensitive information.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

In the preceding specification, various example embodiments have been described with reference to the accompanying drawings. It will, however, be evident that various modifications and changes may be made thereto, and additional embodiments may be implemented, without departing from the broader scope of the invention as set forth in the claims that follow. The specification and drawings are accordingly to be regarded in an illustrative rather than restrictive sense.

What is claimed is:

1. A method comprising:
determining data type information regarding a data type to be written to a memory device,
wherein the data type information identifies a first data type associated with single-level cell data storage or a second data type associated with triple-level cell data storage or quad-level cell data storage;
selecting, based on the data type information, a sector size for the memory device,
wherein the sector size is a first value when the data type information identifies the first data type,
wherein the sector size is a second value when the data type information identifies the second data type, and
wherein the first value exceeds the second value;
generating a logical to physical (L2P) data structure based on the sector size; and
storing the L2P data structure in a memory of a controller of the memory device.

2. The method of claim 1, wherein the sector size is the first value when the data type information identifies the second data type and when data is to be written to the memory device using a sequential write operation.

3. The method of claim 2, wherein the sector size is the second value when the data type information identifies the second data type and when data is to be written to the memory device using a random write operation.

4. The method of claim 1, comprising:
encoding data, using an error correction code (ECC) component, to obtain encoded data,
wherein a size of the data is based on the sector size, and
wherein the data is received from a host computing device; and
storing, based on the L2P data structure, the encoded data in a location of the memory device.

5. The method of claim 4, wherein the size of the data is the first value when the sector size is the first value, and
wherein the size of the data is the second value when the sector size is the second value.

6. The method of claim 1, comprising:
receiving information regarding the first data type associated with single-level cell data storage; and
receiving a request to store data of the operating system.

7. The method of claim 1, comprising:
receiving information regarding the first data type associated with single-level cell data storage; and
receiving a request to store firmware metadata.

8. A memory device comprising:
a controller to:
receive, from an operating system, a request to store first data,
receive, from the operating system, first data type information regarding a first data type,
wherein the first data type is associated with single-level cell data storage;
select, based on the first data type information, a first sector size of a first sector of the memory device;
generate first logical block addresses, of a logical to physical (L2P) data structure, based on the first sector size;
store the first data based on the first logical block addresses;
receive, from the operating system, a request to store second data;
receive, from the operating system, second data type information regarding a second data type,
wherein the second data type is associated with triple-level cell data storage or quad-level cell data storage;
select, based on the second data type information, a second sector size of a second sector of the memory device,
wherein the first sector size exceeds the second sector size;
generate second logical block addresses, of the L2P data structure, based on the second sector size; and
store the second data based on the second logical block addresses.

9. The system of claim 8, wherein the controller is to:
store the L2P data structure in a memory of the controller of the memory device.

10. The system of claim 8, wherein the controller is to:
store the first data in a first portion, of the memory device, dedicated to data of the first data type based on the first logical block addresses.

11. The system of claim 10, wherein the controller is to:
store the second data in a second portion, of the memory device, dedicated to data of the second data type based on the second logical block addresses.

12. The system of claim 8, wherein the controller is to:
encode a portion of the first data, using an error correction code (ECC) component, to obtain encoded first data,
wherein a size of the portion of the first data is based on the first sector size; and
store the encoded first data in a first location of the memory device.

13. The system of claim 12, wherein the controller is to:
encode a portion of the second data, using the ECC component, to obtain encoded second data,
wherein a size of the portion of the second data is based on the second sector size; and
store the encoded second data in a second location of the memory device.

14. The system of claim 8, wherein the first data includes firmware metadata or data of the operating system.

15. A computer program product comprising:
one or more computer readable storage media, and program instructions collectively stored on the one or more computer readable storage media, the program instructions comprising:
program instructions to receive, from an operating system of a host computing device, a request to store data;
program instructions to determine whether the data is associated with single-level cell data storage;
program instructions to select a sector size of a sector of a memory device based on determining whether the data is associated with single-level cell data storage,
wherein the sector size is a first value when the data is associated with single-level cell data storage, and
wherein the sector size is a second value when the data is not associated with single-level cell data storage;
program instructions to generate logical block addresses, of a logical to physical (L2P) data structure, based on the sector size; and
program instructions to store the data based on the logical block addresses.

16. The computer program product of claim 15, wherein the program instructions comprise:
program instructions to determine that the data is associated with single-level cell data storage; and
program instructions to select the first value as the sector size based on determining that the data is associated with single-level cell data storage.

17. The computer program product of claim 16, wherein the program instructions comprise:
program instructions to encode a portion of the data, using an error correction code (ECC) component, to obtain encoded data,
wherein a size of the portion of the data is based on the first value; and
store the encoded data in a location of the memory device based on the L2P data structure.

18. The computer program product of claim 16, wherein the data includes firmware metadata or data of the operating system.

19. The computer program product of claim 15, wherein the program instructions comprise:
program instructions to determine that the data is not associated with single-level cell data storage; and
program instructions to select the second value as the sector size based on determining that the data is not associated with single-level cell data storage.

20. The computer program product of claim 15. wherein the sector size is a second value when the data is associated with triple-level cell data storage or quad-level cell data storage.
